(19) United States
(12) Patent Application Publication
(10) Pub. No.: US 2026/0092989 A1
(43) Pub. Date: Apr. 2, 2026

(54) PHYSICAL QUANTITY MEASUREMENT APPARATUS

(71) Applicant: Asahi Kasei Microdevices Corporation, Tokyo (JP)

(72) Inventor: Tomohiro YOSHIOKA, Tokyo (JP)

(21) Appl. No.: 19/339,209

(22) Filed: Sep. 24, 2025

(30) Foreign Application Priority Data
Sep. 27, 2024 (JP) 2024-168364

(51) Int. Cl. G01R 33/00; G01D 5/14; G01R 33/07

(52) U.S. Cl. CPC G01R 33/0029; G01D 5/142; G01R 33/07

(57) ABSTRACT

Provided is a physical quantity measurement apparatus, comprising: an element with a bridge resistor, which outputs an analog signal representing physical quantities to be measured according to a flow of a driving current; an AD converter which converts the analog signal output from the element into a digital signal; a current mirror circuit which duplicates the driving current flowing through the element as a duplicated current; and a generation circuit which generates a reference voltage in order to output the duplicated current to the AD converter by current-to-voltage conversion.

The contents of the following patent application(s) are incorporated herein by reference: NO. 2024-168364 filed in JP on Sep. 27, 2024.

### BACKGROUND

### 1. Technical Field

The present invention relates to a physical quantity measurement apparatus, a reference voltage generation apparatus, and a sensor.

### 2. Related Art

In Patent Document 1, it is described that “a magnetic sensor that performs AD conversion of Hall effect voltage signals detected by a constant voltage driven Hall element using a reference voltage ADVR generated by a replica Hall element.”

In Patent Document 2, a magnetic detection apparatus that “eliminates the offset voltage of the Hall element and the offset voltage of the amplifier that amplifies the output of the Hall element” is described.

### RELATED ART DOCUMENTS

### Patent Document

Patent Document 1: Japanese Patent Application Publication No. 2015-99089
Patent Document 2: Japanese Patent Application Publication No. 2005-283503

### BRIEF DESCRIPTION OF THE DRAWINGS

FIG. 1 shows an example of a circuit and a configuration included in a physical quantity measurement apparatus 100 of the present embodiment.

FIG. 2A shows an example of a connection relationship of a Hall element 40.

FIG. 2B shows an example of another connection relationship different from FIG. 2A of the Hall element 40.

FIG. 3 shows another example of the circuit and the configuration included in the physical quantity measurement apparatus 100 of the present embodiment.

FIG. 4 is a circuit diagram showing an example of a configuration of an IV conversion circuit 85a.

FIG. 5 is a circuit diagram showing an example of a configuration of an IV conversion circuit 85b.

FIG. 6 shows, furthermore, another example of the circuit and the configuration included in the physical quantity measurement apparatus 100 of the present embodiment.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to a solution of the invention.

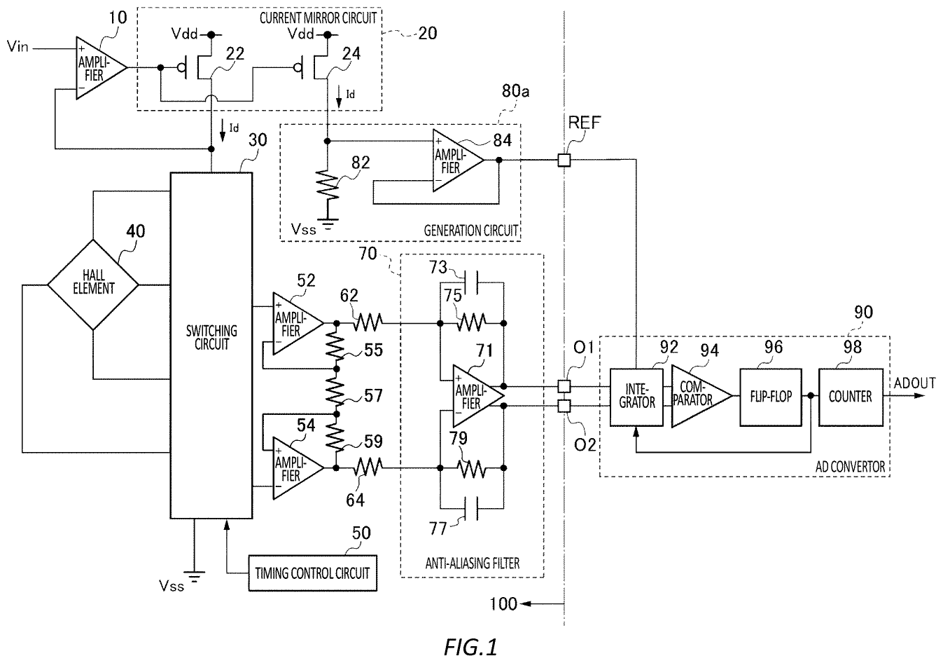

FIG. 1 shows an example of a circuit and a configuration included in a physical quantity measurement apparatus 100 of the present embodiment. The physical quantity measurement apparatus 100 is configured to include an amplifier 10, a current mirror circuit 20, a switching circuit 30, a Hall element 40, a timing control circuit 50, an anti-aliasing filter 70, a generation circuit 80a, and an AD (Analog to digital) converter 90.

The physical quantity measurement apparatus 100 measures physical quantities such as magnetic field, speed, and/or acceleration as analog values, and outputs measured physical quantities as digital-converted digital values by an element including a bridge circuit such as the Hall element 40 or the like.

In this case, in the physical quantity measurement apparatus 100, a reference voltage is input to the AD converter 90 in order to reduce effects caused by temperature characteristics of the element. The physical quantity measurement apparatus 100 of the present embodiment can provide the reference voltage with a simple configuration and counteract the effects of the offset voltage of the element.

An input voltage Vin is input to the amplifier 10, which constitutes a voltage follower based on the input voltage. By controlling a gate voltage of a MOS transistor of the current mirror circuit 20, the MOS transistor of the current mirror circuit 20 is controlled as a current source. The input voltage Vin input to the amplifier 10 may be supplied as a constant voltage. In this manner, the physical quantity measurement apparatus 100 of the present embodiment functions as a physical quantity measurement apparatus that drives the Hall element 40 with the constant voltage. That is, the amplifier 10 is an example of a “power supply unit” for the Hall element 40, which controls the driving current Id such that the driving voltage applied to the element is constant, and supplies it to the element.

In the present embodiment, although a constant voltage driven circuit that drives the Hall element 40 with the constant voltage is shown, the power supply that drives the Hall element 40 is not limited to a constant voltage power supply, and may use a power supply or the like that supplies a constant current, for example.

The current mirror circuit 20 mirrors the driving current Id to provide it to the generation circuit 80a while supplying the driving current Id for driving the Hall element 40 based on a power supply voltage Vdd and an input voltage Vin. The current mirror circuit 20 includes a MOS transistor 22 and a MOS transistor 24.

The MOS transistor 22 and the MOS transistor 24 are P-type MOS transistors, and source electrodes of the MOS transistor 22 and the MOS transistor 24 are connected to a power supply line that applies the voltage Vdd. On the other hand, gate electrodes of the MOS transistor 22 and the MOS transistor 24 are connected in parallel to the amplifier 10 in parallel.

In the present embodiment, sizes of the MOS transistor 22 and the MOS transistor 24 are set equally. The gate voltages applied to the MOS transistor 22 and the MOS transistor 24 are equal, and the same voltage Vdd is applied to the source electrodes of the MOS transistor 22 and the MOS transistor 24. Accordingly, a source-drain current of the MOS transistor 22 and a source-drain current of the MOS transistor 24 are equal, and the drain electrode of the MOS transistor 22 and the drain electrode of the MOS transistor 24 supply a duplicated current obtained by duplicating a current with a magnitude equal to the driving current Id. In this manner, the current mirror circuit 20 is configured. The drain electrode of the MOS transistor 22 is connected to the Hall element 40, and supplies the driving current Id of the Hall element 40 to the Hall element 40.

Note that the sizes of the MOS transistor 22 and the MOS transistor 24 do not require to be limited to be set equally. A variation of a current flowing through the MOS transistor 24 only has to be able to follow a variation of a current flowing through the MOS transistor 22. For example, the size of the MOS transistor 24 may be smaller with respect to the MOS transistor 22, and the current flowing through the MOS transistor 24 may be smaller than the current flowing through the MOS transistor 22. In this manner, the current flowing through the MOS transistor 24 may be increased or decreased in proportion to the current flowing through the sensor element such as the Hall element 40 or the like, and the absolute value of the current flowing through the MOS transistor 24 may be designed arbitrarily according to the desired power consumption or the like.

When the Hall element 40 detects a magnetic field and supplies a Hall voltage, or when the Hall element 40 fluctuates with temperature, the resistor that constitutes the Hall element 40 fluctuates due to the temperature characteristics. The Hall element 40 of the present embodiment is driven by the constant voltage, but when the resistance value of the Hall element 40 fluctuates, the driving current of the Hall element 40, that is, the source-drain current of the MOS transistor 22, fluctuates. The gate voltage of the MOS transistor 22 is set equal to the gate voltage of the MOS transistor 24, and when the source-drain current of the MOS transistor 22 fluctuates, the source-drain current of the MOS transistor 24 fluctuates to duplicate the source-drain current of the MOS transistor 22.

The switching circuit 30 switches a connection relationship of the bridge circuit in the Hall element 40 by interchanging the terminal pair in the input direction and the terminal pair in the output direction to the Hall element 40. In this manner, the effect of offsets in the output voltage due to manufacturing tolerance or the like in the resistors in the Hall element 40 can be reduced.

The switching circuit 30 switches the role of four terminals of the Hall element 40 by switching the connection relationship between the four terminals of the Hall element 40. In this manner, the configuration of the switching circuit 30, the Hall element 40, and the timing control circuit 50 can implement the so-called spinning current method of the Hall element 40 and reduce the effect of resistor offsets in the bridge circuit that becomes an equivalent circuit of the Hall element 40. Specifically, the four terminals of the Hall element 40 are: the terminal to which the input voltage Vin is applied and the driving current Id is supplied, the terminal connected to the internal ground (internal ground voltage Vss), the terminal set to the positive Hall voltage, and the terminal set to the negative Hall voltage. Accordingly, at one end, the switching circuit 30 is connected to the drain terminal of the MOS transistor 22, the internal ground, and the non-inverting input terminal of the amplifier 52 and the inverting output terminal of the amplifier 54 to which the differential voltage that is the output from the Hall element 40 is supplied. On the other hand, the other end of the switching circuit 30 is connected to the four terminals of the Hall element 40.

The switching of the connection relationship performed by the switching circuit 30 may be controlled by the timing control circuit 50. For example, switching of the connection relationship of the switching circuit 30 may be performed by different voltages being supplied by the timing control circuit 50, but the control manner of the switching is not limited.

The Hall element 40 is an element that outputs electromotive force generated according to the surrounding magnetic field as an analog signal. The Hall element 40 can be expressed as a resistor bridge circuit, and one of the two diagonal terminals of this resistor bridge circuit is connected to the terminal to which the input voltage Vin is applied, and the other is connected to the internal ground (Vss). This terminal pair is an example of a “first terminal pair” to which the driving current Id is input or from which an analog signal indicating the Hall effect voltage is output when the connection relationship of the terminal pair is switched by the spinning current method. In this manner, an applied voltage (Vin-Vss) is applied to these two terminals arranged on diagonal sides of the Hall element 40, and the Hall element driving current Id flows to the MOS transistor 22.

In the present embodiment, the Hall element 40 is used in the physical quantity measurement apparatus 100 as an element to measure a physical quantity, but an analog element with a bridge resistor may be used, which indicates the physical quantity to be measured according to the flow of the driving current, and the Hall element is only an example. Elements that measure physical quantities may be elements that measure physical quantities such as magnetic field, speed, and/or acceleration as analog values. When the surrounding magnetic field fluctuates with this current flowing, a Hall effect voltage (VHP-VHN) according to the magnetic field fluctuation between another two diagonal terminals (VHP, VHN) is generated. In this manner, the fluctuation of the magnetic field can be detected. These two terminals are an example of the “second terminal pair”, from which the analog signals indicating the Hall effect voltage are output when the driving current is input to the first terminal pair, and to which the driving current is input when the analog signals indicating the Hall effect voltage from the first terminal pair are output.

Accordingly, the switching circuit 30 corresponds to a circuit that switches a terminal pair through which the driving current flows and a terminal pair that outputs analog signals between the first terminal pair and the second terminal pair.

The timing control circuit 50 switches a timing when the switching circuit 30 switches the connection relationship of the Hall element 40. In the Hall element 40, at four terminals arranged on the quadrilateral of the bridge circuit, a voltage (input voltage Vin and internal ground Vss) is applied to the diagonal, and the Hall voltage from the other two diagonal terminals is read.

Accordingly, switching the connection relationship of these terminals by the timing control circuit 50 corresponds to switching the voltage by 90 degrees. Since the sum of the interior angles of a quadrangle is 360 degrees, the timing control circuit 50 will switch the relative connection angles between 0 degrees (the setting of 360×n degrees (n is an integer) obtains the same value), 90 degrees, 180 degrees, and 270 degrees. As an example, the timing control circuit 50 may perform a plurality of cycles of switching, each cycle consisting of taking one value of each of these four connection angles. The interval between switching timings controlled by the timing control circuit 50 may be sufficiently faster in speed than the rise in the temperature of the Hall element 40. In particular, the interval between switching timings controlled by the timing control circuit 50 may be so short an interval that the effect of the change in resistor due to the temperature characteristic of the Hall element 40 in each cycle is negligible.

The amplifier 52 constitutes a non-inverting amplification circuit. One of the Hall voltages of the Hall element 40 (for example, VHP) is applied to the non-inverting input terminal of the amplifier 52.

On the other hand, the amplifier 54 constitutes an inverting amplification circuit. Another of the Hall voltage of the Hall element 40 (for example, VHN) is applied to the inverting input terminal of the amplifier 54.

Resistors 55, 57, 59 are resistors for allowing the amplifier 52 and the amplifier 54 to function as amplification circuits and resistors for adjusting the differential output voltage. Resistors 62, 64 are resistors for adjusting the differential output voltage, and also function as resistors for performing low pass filtering on each of the differential voltages in the anti-aliasing filter 70.

The anti-aliasing filter 70 is a low-pass filter that acts to prevent folding (aliasing) errors from appearing in the converted signal when the AD converter 90 performs AD conversion. The anti-aliasing filter 70 of the present embodiment performs low pass filtering on each of the differential voltages. The anti-aliasing filter 70 of the present embodiment is configured to include an amplifier 71, a capacitor 73, a resistor 75, a capacitor 77 and a resistor 79.

A resistor 62 that is one of the resistors for adjusting differential voltage input to the anti-aliasing filter 70, the amplifier 71, the capacitor 73, and the resistor 75 constitutes a low-pass filter. On the other hand, a resistor 64, the amplifier 71, the resistor 75 and the capacitor 77 also constitute a low-pass filter. In this manner, at any differential voltage output by the amplifier 52 and the amplifier 54, the low pass filtering is performed. The anti-aliasing filter 70 applies the output differential voltage on each of a terminal O1 and a terminal O2.

The generation circuit 80a generates a reference voltage ADVREF when the AD converter 90 performs AD conversion, according to the duplicated current obtained by duplicating the driving current Id of the Hall element 40 supplied from the current mirror circuit 20. The generation circuit 80a applies the reference voltage ADVREF to a terminal REF. The generation circuit 80a includes a resistor 82 and an amplifier 84.

In the figure, although the generation circuit 80a is shown as a circuit that constitutes an integrated circuit on the same chip as the physical quantity measurement apparatus 100, the generation circuit 80a and the AD converter 90 may be provided on chip different from the Hall element 40 that constitutes the sensor element to constitute a “reference voltage generation apparatus”. In this case, the current mirror circuit 20 may be provided on a sensor side, and the duplicated current may be output toward the generation circuit 80a. In this manner, the terminal that supplies the duplicated current from the current mirror circuit 20 may constitute an “output unit” that outputs the duplicated current.

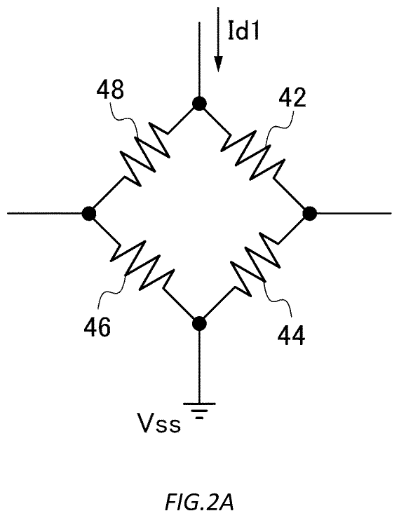

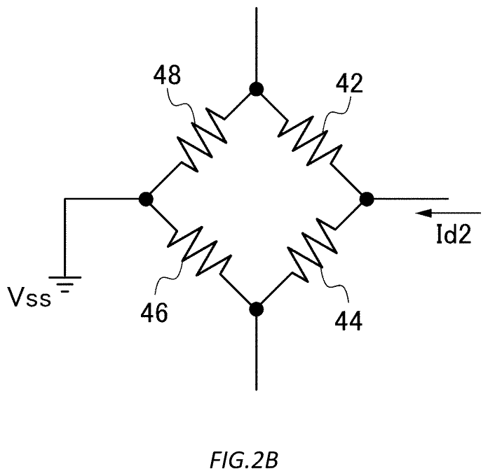

The resistor 82 converts the reference voltage ADVREF based on the current Id. That is, the generation circuit 80a may generate the reference voltage by performing current-to-voltage conversion on the current Id by using the resistor 82. Note that the resistor 82 also has temperature characteristics. The effect due to the temperature characteristics of this resistor 82 may be suppressed by a selection related to the material or composition of the resistor element of the resistor 82. Alternatively, the effect due to temperature characteristics of the resistor 82 may be corrected through another means by obtaining the temperature of the measurement environment. The Hall element 40 is an element in which the Hall effect voltage occurs with the movement of the carriers, such as holes or free electrons or the like. Although the Hall element 40 is represented by a bridge circuit as an equivalent circuit in FIG. 2a or FIG. 2b, etc., described below, temperature variations in carrier mobility have a large effect on the Hall effect voltage from the Hall element 40. The resistor 82 outputs a reference voltage ADVREF based on the current Id, thereby allowing the effect that appears in the Hall effect voltage due to the temperature characteristics of the Hall element 40 to be removed from the output voltage of the AD converter 90.

Instead of the resistor 82, a replica Hall element may be used to generate the reference voltage ADVREF for the AD converter 90 without using the current mirror circuit 20. In this case, the Hall voltage output from the replica Hall element is generated as the reference voltage ADVREF. The temperature characteristics of the replica Hall element can be set close to the temperature characteristics of the Hall element 40. Such a configuration also cancels out the temperature characteristics of the Hall element 40. However, the replica Hall element is about the same size as the Hall element 40, and the footprint cannot be reduced sufficiently when the replica Hall element is used compared to when no replica Hall element is used.

In the present embodiment, the generation circuit 80a is used to generate the reference voltage ADVREF based on the duplicated current of the driving current Id supplied from the current mirror circuit 20. In this manner, the reference voltage ADVREF based on the current value that mirrors the fluctuating driving current Id is output, even if the Hall element 40 rises in temperature and shows different resistance values due to temperature characteristics. The AD converter 90 outputs a digital output value of the Hall effect voltage based on the ratio between the reference voltage ADVREF and the Hall effect voltage of the Hall element 40. Since both the reference voltage ADVREF and the Hall effect voltage fluctuate according to variations in the driving current Id, the effect of fluctuations in the Hall effect voltage due to the temperature characteristics of the Hall element 40 can be removed in the digital output value of the AD converter 90.

The amplifier 84 is a voltage follower. At the non-inverting input terminal of the amplifier 84, a voltage generated based on the driving current Id is applied to the resistor 82. It is short-circuited to the output terminal of the amplifier 84. The output voltage from the amplifier 84, as a reference voltage ADVREF, is applied to the terminal REF.

The AD converter 90 converts the analog signal output from the Hall element 40 into a digital signal. That is, the AD converter 90 functions as an AD converter that converts the analog signal output from the element with the bridge resistor, which outputs an analog signal indicating the physical quantity to be measured according to the flow of the driving current, into a digital signal.

Regarding the AD converter 90, in this example, although an example is described that the signal based on the voltage value applied to the terminal O1 and the terminal O2 and the reference voltage ADVREF are integrated at the same timing, a double integration type where the input signal VIN and the reference voltage ADVREF are integrated at different timings may be used. The AD converter 90 may also be any AD converter that outputs a digital signal according to the ratio of the signal based on the voltage value applied to the terminal O1 and the terminal O2 to the reference voltage ADVREF, a 42 type AD converter may be used, or an integral type AD converter may be used. Note that although the AD converter 90 is shown in the figure as a configuration external to the chip of the physical quantity measurement apparatus 100, the entire integrated circuit may be a configuration provided on a single chip, with the entire generation circuit 80 and the AD converter 90 as circuit elements in an integrated circuit constituting the physical quantity measurement apparatus 100. The AD converter 90 in the present embodiment includes an integrator 92, a comparator 94, a flip-flop 96 and a counter 98. The integrator 92 and the comparator 94 function as the analog output signal in the AD converter 90, and the flip-flop 96 and the counter 98 function as the digital signal output unit in the AD converter 90.

The integrator 92 functions as an input adder that adds the reference voltage ADVREF in relation to the signal, switching the polarity by forwarding or inverting and integrating. However, a single-ended differential signal converter or the like may be provided between the integrator 92 and the terminal O1 and the terminal O2, or a device that converts the signal from the Hall element may be provided as a single-ended signal. In this case, the values of the single-ended signal relative to the reference voltage ADVREF are added during integration.

The comparator 94 functions as a determination unit of the analog output signal, which amplifies the output added input signal from the integrator 92, which is an input adder, to generate an analog output signal having a predetermined amplitude, and compares the magnitude of the amplitude of this analog output signal with a predetermined voltage to perform determination.

The flip-flop 96 and the counter 98 function as a digital signal output unit. The digital signal output unit calculates a count value based on the signal indicating the magnitude determination result of the analog output signal output from the comparator 94, and outputs this count value as a digital signal. The output of the flip-flop 96 is also input to the integrator 92 to switch and add the reference voltage ADVREF in the integrator 92. The counter 98 counts the conversion value and outputs a digital signal of the counted level as a digital value. The reference voltage ADVREF in the AD converter 90 may be adjusted so that the effect of the temperature characteristics of the resistor 82 does not affect the digital signal of the Hall voltage detection result.

FIG. 2A shows an example of the connection relationship of the Hall element 40. The Hall element 40 is configured to include a resistor 42, a resistor 44, a resistor 46 and a resistor 48.

In this manner, the Hall element 40 is described as a bridge circuit, as an equivalent circuit, including four resistors 42, 44, 46, 48. These four resistors 42, 44, 46, 48 may have offsets due to manufacturing tolerances or other causes. The Hall element 40 of the present embodiment is driven by a constant voltage, and as in FIG. 1, the driving voltage is expressed as Vin. Also in the following, the internal ground voltage Vss is calculated as Vss=0.

The resistance value of the resistor 42 shall have a resistance value of R. In this case, if the other three resistors have an offset with reference to the resistor R, the resistance value of the resistor 44 is R+ΔR1, the resistance value of resistor 46 is R+ΔR2, and the resistance value of resistor 48 is R+ΔR3. In this manner, when there is an offset in the four resistors of the resistor 42, the resistor 44, the resistor 46 and the resistor 48, the offset resistance value can be defined with reference to the resistance value of any one of the four resistors.

In the following, calculation is performed regarding the effect of the offset resistance values in the four resistors 42, 44, 46, 48 on the voltage values output from the bridge circuit. In the present embodiment, the reference voltages ADVREF1 and ADVREF2 of the AD converter 90 are generated from the current values that mirror the driving currents Id1 and Id2 of the Hall element. In this manner, the effect of the offset resistance values in the four resistors 42, 44, 46, 48 in the output value of the AD converter 90 based on the voltage output from the bridge circuit is cancelled.

In the formula for the output voltage value of the Hall element 40 calculated below, if the bridge circuit is a sensor element such as the Hall element 40, the detected voltage will be superimposed on the output voltage value. In the following calculations, for simplicity, the output voltage value due to detection is set to 0 to confirm how the effect due to the offset resistor cancels out.

In this case, the composite resistor of this bridge circuit is expressed by the following formula (1).

$${R}_{total 1} = \frac{( 2 R + Δ R 1 ) \times ( 2 R + Δ R 2 + Δ R 3 )}{4 R + Δ R 1 + Δ R 2 + Δ R 3} \qquad ( 1 )$$

Accordingly, the driving current Id 1 of the Hall element flowing into the Hall element is expressed by the following formula (2).

$$Id 1 = \frac{V}{\frac{( 2 R + Δ R 1 ) \times ( 2 R + Δ R 2 + Δ R 3 )}{4 R + Δ R 1 + Δ R 2 + Δ R 3}} \qquad ( 2 )$$

In the present embodiment, the current mirror circuit 20 causes a current of a magnitude equal to the driving current Id 1 of the Hall element to flow into the resistor of the IV conversion circuit 85. If the magnitude of the resistor of the IV conversion circuit 85 is R′, the reference voltage ADVREF1 of the AD converter 90 is expressed by the following formula (3).

$$ADVREF 1 = \frac{V}{\frac{( 2 R + Δ R 1 ) \times ( 2 R + Δ R 2 + Δ R 3 )}{4 R + Δ R 1 + Δ R 2 + Δ R 3}} \times {R}^{′} \qquad ( 3 )$$

The differential voltage SensO1 of the Hall element is expressed by the following formula (4).

$$SensO 1 = \frac{R + Δ R 2}{2 R + Δ R 2 + Δ R 3} V - \frac{R + Δ R 1}{2 R + Δ R 1} V \qquad ( 4 )$$

It is expressed by the formula (3) and the formula (4). Depending on the voltage ratio, the digital voltage ADOUT1 output from the AD converter 90 is expressed by formula (5).

$$ADOUT 1 = \frac{\frac{R + Δ R 2}{2 R + Δ R 2 + Δ R 3} V - \frac{R + Δ R 1}{2 R + Δ R 1} V}{\frac{V}{\frac{( 2 R + Δ R 1 ) \times ( 2 R + Δ R 2 + Δ R 3 )}{4 R + Δ R 1 + Δ R 2 + Δ R 3}} \times {R}^{′}} \qquad ( 5 )$$

Next, it will be explained with reference to FIG. 2B how the voltage from the AD converter 90 is given by the calculation formula in the spinning current method, with the connection relationship of the 40 Hall elements rotated by 90 degrees.

FIG. 2B shows an example of another connection relationship different from FIG. 2A of the Hall element 40. The switching circuit 30 rotates the connection relationship of the Hall element 40 by 90 degrees with respect to FIG. 2A.

In this case, since the connection relationship changes, the formula for the composite resistor is expressed by the following formula (6).

$${R}_{total 2} = \frac{( 2 R + Δ R 1 + Δ R 2 ) \times ( 2 R + Δ R 3 )}{4 R + Δ R 1 + Δ R 2 + Δ R 3} \qquad ( 6 )$$

Accordingly, the driving current Id 2 of the Hall element flowing into the Hall element is expressed by the following formula (7).

$$Id 2 = \frac{V}{\frac{( 2 R + Δ R 1 + Δ R 2 ) \times ( 2 R + Δ R 3 )}{4 R + Δ R 1 + Δ R 2 + Δ R 3}} \qquad ( 7 )$$

In the present embodiment, the current mirror circuit 20 causes a current of a magnitude equal to the driving current Id 1 of the Hall element to flow into the resistor of the IV conversion circuit 85. If the magnitude of the resistor of the IV conversion circuit 85 is R′, the reference voltage ADVREF2 of the AD converter 90 is expressed by the following formula (8).

$$ADVREF 2 = \frac{V}{\frac{( 2 R + Δ R 1 + Δ R 2 ) \times ( 2 R + Δ R 3 )}{4 R + Δ R 1 + Δ R 2 + Δ R 3}} \times {R}^{′} \qquad ( 8 )$$

The differential voltage SensO2 of the Hall element is given by the following formula (9).

$$SensO 2 = \frac{R + Δ R 2}{2 R + Δ R 1 + Δ R 2} V - \frac{R + Δ R 3}{2 R + Δ R 3} V \qquad ( 9 )$$

Depending on the voltage ratios expressed in the formula (8) and the formula (9), the digital voltage ADOUT2 output from the AD converter 90 is expressed by the following formula (10).

$$ADOUT 2 = \frac{\frac{R + Δ R 2}{2 R + Δ R 1 + Δ R 2} V - \frac{R + Δ R 3}{2 R + Δ R 3} V}{\frac{V}{\frac{( 2 R + Δ R 1 + Δ R 2 ) \times ( 2 R + Δ R 3 )}{4 R + Δ R 1 + Δ R 2 + Δ R 3}} \times {R}^{′}} \qquad ( 10 )$$

Accordingly, the value obtained by adding ADOUT1 and ADOUT2 is expressed by the following formula (11).

$$ADOUT 1 + ADOUT 2 = \frac{1}{{R}^{′} ( 4 R + Δ R 1 + Δ R 2 + Δ R 3 )} \times [ ( R + Δ R 2 ) ( 2 R + Δ R 1 ) - ( R + Δ R 1 ) ( 2 R + Δ R 2 + Δ R 3 ) + ( R + Δ R 2 ) ( 2 R + Δ R 3 ) - ( R + Δ R 3 ) ( 2 R + Δ R 1 + Δ R 2 ) ] = 0 \qquad ( 11 )$$

Expanding the right side of formula (11), it can be seen that ADOUT1+ADOUT2=0, indicating that this formula cancels out.

Accordingly, by using the spinning current method, the effect of the offset resistance value does not appear in the output of the AD converter 90. In the configuration of the physical quantity measurement apparatus 100 of the present embodiment, a replica Hall element is not used, and the value obtained by multiplying the duplicated current of the driving current Id by the resistor R′ of the resistor 82 in the formula (3) and the formula (4) is derived as the reference voltage ADVREF of the AD converter 90. When a replica Hall element is used to generate the reference voltage ADVREF, the offset between the resistor constituting the replica Hall element and the resistor constituting the Hall element 40 can be different, even if the replica Hall element can reproduce the temperature characteristics of the Hall element 40. Details are omitted, but in this case, calculating ADOUT1+ADOUT2 does not result in a canceling relationship as in formula (11). Accordingly, when the replica Hall element is used, the offset resistor of the Hall element 40 and the replica Hall element may become to be affected. Although a circuit that uses the replica Hall element to generate a reference voltage of the AD converter 90 can be effective in canceling the temperature characteristics of the Hall element, a configuration referring to the driving current Id of the Hall element 40 when generating the reference voltage ADVREF, as in the present embodiment, can be more effective in the point of canceling the offset of the resistor. Accordingly, the configuration of the physical quantity measurement apparatus 100 in the present embodiment is effective not only in reducing the footprint by not using the replica Hall element, but also in the point of canceling the resistor offset.

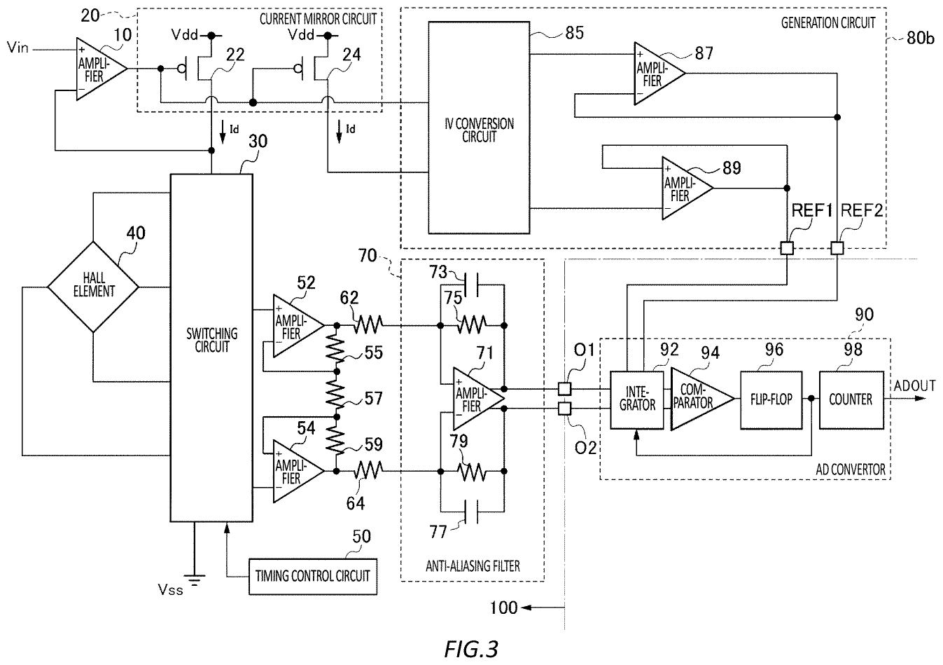

FIG. 3 shows another example of the circuit and the configuration included in the physical quantity measurement apparatus 100 of the present embodiment. In the following, the physical quantity measurement apparatus 100 shown in FIG. 3 is described, focusing mainly on the differences from the embodiment shown in FIG. 1. The physical quantity measurement apparatus 100 in the present embodiment includes a generation circuit 80b in place of the generation circuit 80a.

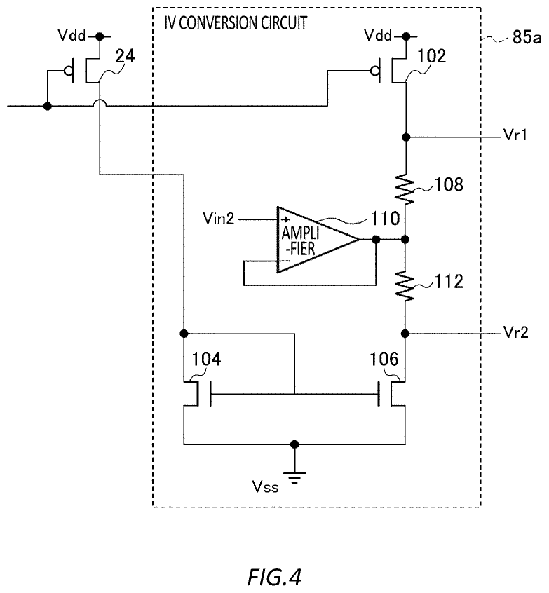

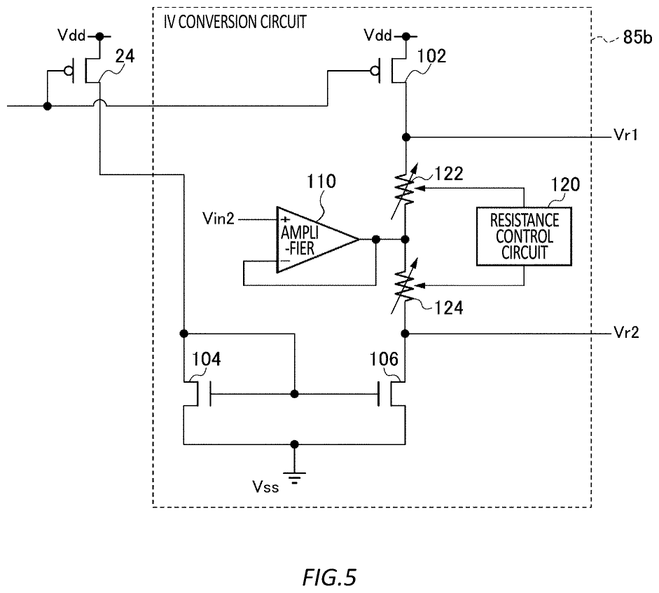

The generation circuit 80b is a circuit that generates a reference voltage as a differential voltage. The generation circuit 80b includes an IV conversion circuit 85, an amplifier 87 and an amplifier 89. The specific configuration of the IV conversion circuit 85 is described in detail, referring to FIG. 4 and FIG. 5.

The output from the IV conversion circuit 85 is input to the non-inverting input terminal of the amplifier 87, and the amplifier 87 outputs a positive reference voltage of the reference voltage, which is a differential voltage. On the other hand, the output from the IV conversion circuit 85 is input to the inverting input terminal of the amplifier 89, and the amplifier 87 outputs a negative reference voltage of the reference voltage, which is a differential voltage. The amplifier 87 and the amplifier 89 function as voltage followers and apply their respective output voltages to the terminal REF1 and the terminal REF2. In this manner, a reference voltage as a differential voltage is output, and the AD converter 90 in the present embodiment operates using the reference voltage of the differential voltage.

FIG. 4 is a circuit diagram showing an example of the configuration of the IV conversion circuit 85a. IV conversion circuit 85 in FIG. 3 may be the IV conversion circuit 85a of the present embodiment. The IV conversion circuit 85a includes a MOS transistor 102, a MOS transistor 104, and a MOS transistor 106, a resistor 108, an amplifier 110 and a resistor 112.

The MOS transistor 102 functions as a current source that supplies a current referring to a source-drain current flowing through the MOS transistor 24. The MOS transistor 102 is a PMOS transistor.

The MOS transistor 104 and the MOS transistor 106 are NMOS transistors. The MOS transistor 104 is a transistor for referring to the MOS transistor 106.

The magnitude of the Drain-source current flowing through the MOS transistor 106 is a current of a magnitude referring to the magnitude of the Drain-source current flowing through the MOS transistor 104. The gate terminal of the MOS transistor 104 is connected to the gate terminal of the MOS transistor 106. The drain terminal of the MOS transistor 104 is further short-circuited with the gate terminal of the MOS transistor 104 and the gate terminal of the MOS transistor 106. The source terminals of the MOS transistor 104 and the MOS transistor 106 are connected together to the internal ground (internal ground potential Vss). In a case of such a connection relationship, the drain-source current flowing in the MOS transistor 106 is a magnitude according to the size ratio of MOS transistor 104 and MOS transistor 106 relative to the drain-to-source current flowing in the MOS transistor 104. In particular, when the sizes of the MOS transistor 104 and the MOS transistor 106 are equal, the MOS transistor 104 and the MOS transistor 106 constitute the current mirror circuit.

The resistor 108 performs IV conversion by resistance value based on the driving current Id mirrored by the MOS transistor 102. In this manner, the reference voltage Vr1 occurred between the drain terminal of the MOS transistor 102 and the resistor 108 is generated, and the reference voltage is applied to the terminal REF 2 via the amplifier 87 which is the voltage follower.

A current referring to the reference current flowing into the MOS transistor 106 flows through the resistor 112. The connection points of the resistor 108 and the resistor 112 are supplied with a voltage using the amplifier 110. In this manner, the reference voltage Vr2 is generated, and the reference voltage is applied to the terminal REF 1 via the amplifier 89 which is a voltage follower.

FIG. 5 is a circuit diagram showing an example of a configuration of the IV conversion circuit 85b. The IV conversion circuit 85 in FIG. 3 may be the IV conversion circuit 85b in the present embodiment. Descriptions will focus mainly on the differences from the IV conversion circuit 85a.

The IV conversion circuit 85b includes a variable resistor 122 and a variable resistor 124 in place of the fixed resistors 108 and 112 of the IV conversion circuit 85a. The resistance values of the variable resistor 122 and the variable resistor 124 are controlled by the resistor control circuit 120. The resistor control circuit 120 may control the resistance values of the variable resistor 122 and the variable resistor 124 based on values stored in a memory device (not shown). By using the IV conversion circuit 85b in FIG. 5, a reference voltage with the desired differential voltage can be output based on the driving current of the Hall element 40.

Such a configuration allows the reference voltage of the AD converter 90 as a differential voltage to be supplied using the generation circuit 80b. In this manner, even if in the embodiments shown in FIGS. 3 to 5, which use reference voltages that are differential voltages, the temperature characteristics of the Hall element 40 can be compensated by a simple configuration with a reduced footprint without using a replica Hall element, and the effect of the offset of the resistor that constitutes the Hall element 40 can also be reduced.

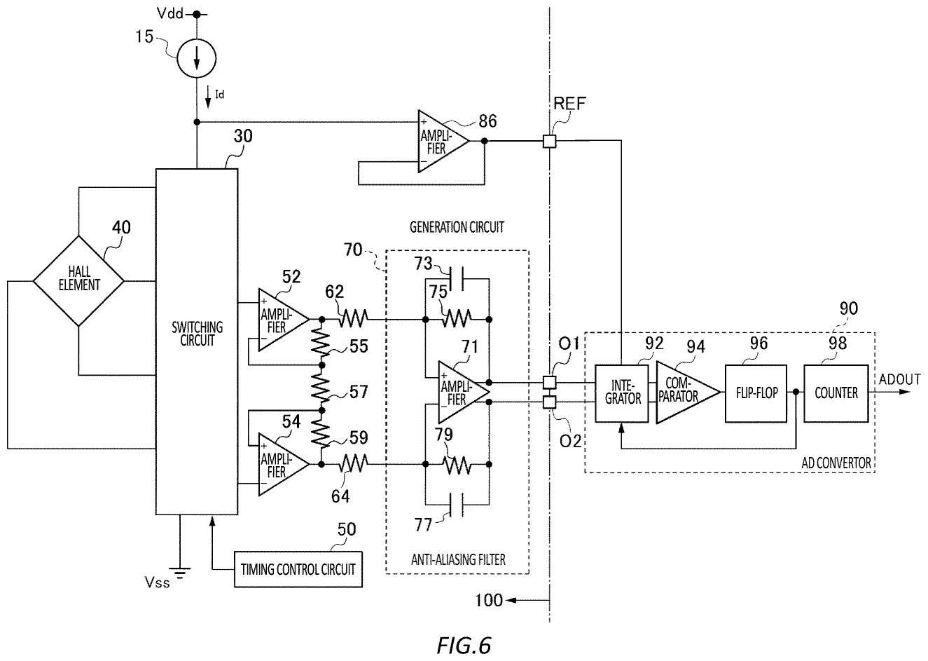

FIG. 6 shows, furthermore, another example of the circuit and the configuration included in the physical quantity measurement apparatus 100 of the present embodiment. In the following, regarding the physical quantity measurement apparatus 100 in the present embodiment, descriptions will focus on differences with the physical quantity measurement apparatus 100 described in FIG. 1. The physical quantity measurement apparatus 100 in the present embodiment includes a constant current source 15 and an amplifier 86 instead of the amplifier 10, the current mirror circuit 20 and the generation circuit 80. The physical quantity measurement apparatus 100 in the present embodiment is common with the physical quantity measurement apparatus 100 in FIG. 1 in another configuration.

The constant current source 15 is a current source that supplies a constant current to the Hall element 40. The constant current source 15 is connected to the power supply line that supplies the voltage Vdd. In the embodiment in FIG. 1, although the physical quantity measurement apparatus 100 drives the Hall element 40 with a constant voltage by the voltage supplied from the amplifier 10, the constant current source 15 in the present embodiment drives the Hall element 40 with a constant current.

Since the resistance value of the Hall element 40 fluctuates with the temperature characteristics of the Hall element 40, the voltage supplied from the constant current source 15 to the Hall element 40 via the switching circuit 30 fluctuates. The non-inverting input terminal of the amplifier 86 is supplied with a voltage equal to the voltage supplied to the Hall element 40.

The amplifier 86 has its inverting input terminal short-circuited to its output terminal and outputs a reference voltage ADVREF as a voltage follower. The reference voltage ADVREF is a voltage according to the voltage supplied to the Hall element 40, and thus fluctuates according to the temperature characteristics of the Hall element 40. The output terminal of the amplifier 86 is connected to the terminal REF. In the present embodiment, the reference voltage ADVREF, which fluctuates according to the temperature characteristics of the Hall element 40, is also applied to the terminal REF.

In the present embodiment, the fluctuation of the resistance value of the sensor element such as the Hall element 40 becomes the dynamic range of the reference voltage ADVREF as it is. In cases where the temperature characteristics of the sensor element are small, etc., the circuit of the present embodiment can be used instead of the circuit that drives the Hall element 40 with the constant voltage of FIG. 1. In such a case, the physical quantity measurement apparatus 100 of the present embodiment can also compensate for the temperature characteristics of the Hall element 40 with a simple configuration with a reduced footprint without using a replica Hall element, and can also reduce the effect of the offset of the resistor that constitutes the Hall element 40.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as “first” or “next” for the sake of convenience in the claims, specification, or drawings, it does not necessarily mean that the process must be performed in this order.

### (Other Possible Items)

### (Item 1)

A physical quantity measurement apparatus, comprising:
an element with a bridge resistor, which outputs an analog signal representing physical quantities to be measured according to a flow of a driving current;
an AD converter which converts the analog signal output from the element into a digital signal;
a current mirror circuit which duplicates the driving current flowing through the element as a duplicated current; and
a generation circuit which generates a reference voltage in order to output the duplicated current to the AD converter by current-to-voltage conversion.

### (Item 2)

The physical quantity measurement apparatus according to item 1, wherein the element is a Hall element that is driven by the driving current and outputs electromotive force generated according to a surrounding magnetic field as the analog signal.

### (Item 3)

The physical quantity measurement apparatus according to item 2, wherein:
the Hall element has a first terminal pair to which the driving current is input or the analog signal is output, and a second terminal pair to which the analog signal is output when the driving current is input to the first terminal pair and the driving current is input when the analog signal is output from the first terminal pair; and
the physical quantity measurement apparatus further comprises
a switching circuit which switches a terminal pair that carries a driving current and a terminal pair that outputs the analog signal between the first terminal pair and the second terminal pair.

### (Item 4)

The physical quantity measurement apparatus according to item 1, further comprising a power supply unit which controls the driving current to supply the driving current to the element so that a driving voltage applied to the element is constant.

### (Item 5)

A reference voltage generation apparatus comprising:
an AD converter which converts a analog signal output from an element with a bridge resistor that outputs the analog signal representing physical quantities to be measured according to a flow of a driving current, into a digital signal; and
a generation circuit which generates a reference voltage in order to be output to the AD converter, by performing current-to-voltage conversion on the duplicated current output from a current mirror circuit that duplicates the driving current flowing through the element as a duplicated current.

### (Item 6)

A sensor comprising:
an element with a bridge resistor, which outputs an analog signal representing physical quantities to be measured according to a flow of a driving current;
a current mirror circuit which duplicates the driving current flowing through the element as a duplicated current; and
an output unit which outputs the duplicated current toward a generation circuit which generates a reference voltage in order to output the duplicated current to the AD converter by current-to-voltage conversion.

### (Item 7)

The sensor according to item 6, wherein the element is a Hall element that is driven by the driving current and outputs electromotive force generated according to a surrounding magnetic field as the analog signal.

### EXPLANATION OF REFERENCES

10: amplifier; 15: constant current source; 20: current mirror circuit; 22, 24: MOS transistor; 30: switching circuit; 40: Hall element; 42, 44, 46, 48: resistor; 50: timing control circuit; 52, 54: amplifier; 55, 57, 59, 62, 64: resistor; 70: anti-aliasing filter; 71: amplifier; 73, 77: capacitor; 75, 79: resistor; 80: generation circuit; 82: resistor; 85: IV conversion circuit; 86, 87, 89: amplifier; 90: AD converter; 92: integrator; 94: comparator; 96: flip-flop; 98: counter; 102, 104, 106: MOS transistor; 108, 112: resistor; 110: amplifier; 120: resistor control circuit; 122, 124: variable resistor.

What is claimed is:

1. A physical quantity measurement apparatus, comprising:
an element with a bridge resistor, which outputs an analog signal representing physical quantities to be measured according to a flow of a driving current;
an AD converter which converts the analog signal output from the element into a digital signal;
a current mirror circuit which duplicates the driving current flowing through the element as a duplicated current; and
a generation circuit which generates a reference voltage to be output to the AD converter by performing current-to-voltage conversion on the duplicated current.

2. The physical quantity measurement apparatus according to claim 1, wherein the element is a Hall element that is driven by the driving current and outputs electromotive force generated according to a surrounding magnetic field as the analog signal.

3. The physical quantity measurement apparatus according to claim 2, wherein:
the Hall element has a first terminal pair to which the driving current is input or from which the analog signal is output, and a second terminal pair from which the analog signal is output when the driving current is input to the first terminal pair and to which the driving current is input when the analog signal is output from the first terminal pair; and
the physical quantity measurement apparatus further comprises
a switching circuit which switches a terminal pair that conducts a driving current and a terminal pair that outputs the analog signal between the first terminal pair and the second terminal pair.

4. The physical quantity measurement apparatus according to claim 1, further comprising a power supply unit which supplies the driving current to the element by controlling the driving current such that a driving voltage applied to the element is constant.

5. The physical quantity measurement apparatus according to claim 4, wherein the element is a Hall element that is driven by the driving current and outputs electromotive force generated according to a surrounding magnetic field as the analog signal.

6. The physical quantity measurement apparatus according to claim 5, wherein:
the Hall element has a first terminal pair to which the driving current is input or from which the analog signal is output, and a second terminal pair from which the analog signal is output when the driving current is input to the first terminal pair and to which the driving current is input when the analog signal is output from the first terminal pair; and
the physical quantity measurement apparatus further comprises
a switching circuit which switches a terminal pair that conducts a driving current and a terminal pair that outputs the analog signal between the first terminal pair and the second terminal pair.

7. A reference voltage generation apparatus comprising:
an AD converter which converts an analog signal output from an element with a bridge resistor that outputs the analog signal representing physical quantities to be measured according to a flow of a driving current, into a digital signal; and
a generation circuit which generates a reference voltage to be output to the AD converter, by performing current-to-voltage conversion on the duplicated current output from a current mirror circuit that duplicates the driving current flowing through the element as a duplicated current.

8. The reference voltage generation apparatus according to claim 7, wherein the element is a Hall element that is driven by the driving current and outputs electromotive force generated according to a surrounding magnetic field as the analog signal.

9. A sensor comprising:
an element with a bridge resistor, which outputs an analog signal representing physical quantities to be measured according to a flow of a driving current;
a current mirror circuit which duplicates the driving current flowing through the element as a duplicated current; and
an output unit which outputs the duplicated current toward a generation circuit which generates a reference voltage to be output to the duplicated current by performing current-to-voltage conversion on the AD converter.

10. The sensor according to claim 9, wherein the element is a Hall element that is driven by the driving current and outputs electromotive force generated according to a surrounding magnetic field as the analog signal.
